(19) United States
(12) Patent Application Publication
(10) Pub. No.: US 2021/0110561 A1
(43) Pub. Date: Apr. 15, 2021

(54) SYSTEMS AND METHODS FOR MILLIMETER WAVE ESTIMATION OF BODY GEOMETRY

(71) Applicant: Duke University, Durham, NC (US)

(72) Inventors: Jonah Gollub, San Diego, CA (US); Kenneth Trofatter, Durham, NC (US); Seyedmohammadreza Faghih Imani, Durham, NC (US); David R. Smith, Durham, NC (US)

(21) Appl. No.: 17/067,359

(22) Filed: Oct. 9, 2020

Related U.S. Application Data
(60) Provisional application No. 62/912,859, filed on Oct. 9, 2019.

(51) Int. Cl. G06T 7/60; G06T 7/38; G06T 3/40; G06T 15/50; G06T 17/20; G06F 30/23

(52) U.S. Cl. CPC G06T 7/60; G06T 7/38; G06T 3/4038; G06T 2207/20212; G06T 17/20; G06F 30/23; G06T 2207/10072; G06T 15/503

(57) ABSTRACT

A method for acquiring body measurement information includes: detecting that a subject is in proximity to a flat-panel imaging device; capturing, via the flat-panel imaging device, a plurality of images; processing the plurality of images to build a three-dimensional model of the subject; calculating one or more body measurements of the subject based on the three-dimensional model; and outputting the one or more body measurements.

### CROSS-REFERENCE TO RELATED APPLICATIONS

This application claims the benefit of U.S. Provisional Application No. 62/912,859, filed Oct. 9, 2019, for “Systems and Methods for Millimeter Wave Estimation of Body Geometry,” which is incorporated herein by reference.

### BACKGROUND

Internet shopping and big data have transformed how consumers learn about, purchase, and interact with nearly every conceivable commodity, from automobiles to groceries. However, the experience falls short for those shopping online for clothing due to the challenge of assessing fit and appearance. This uncertainty leads to increased product returns and hesitation by consumers to adopt online apparel shopping. If consumers accurately knew their body's geometry, three-dimensional modeling could simulate virtual clothes to provide realistic visual feedback tailored to the buyer.

Optical scanning devices have been proposed for such applications, but they generally have not caught on. This is arguably because they are inconvenient for consumers to use. People must wear form-fitting clothing during scanning and usually must pose while a scanner is mechanically rotated around them, as in airport security systems.

### SUMMARY

This Summary is provided to introduce a selection of concepts that are further described below in the Detailed Description. This Summary is not intended to identify key or essential features of the claimed subject matter, nor is it intended to be used as an aid in limiting the scope of the claimed subject matter.

The present disclosure addresses the aforementioned shortcoming by providing, in part, a flat-panel imaging device, and methods of using said device, to conveniently measure the geometry of a person's body for apparel shopping, as well as medical and physical fitness applications. A low-cost system in accordance with the present disclosure could be placed in high-traffic areas to give consumers the opportunity to quickly take their body measurements and securely store those measurements on their smart phones and/or share them with online vendors to facilitate clothing purchases and the like.

One aspect of the present disclosure is a method of acquiring body measurement information. The method may include various steps, including: detecting that a subject is in proximity to a flat-panel imaging device; capturing, via the flat-panel imaging device, a plurality of images; processing the plurality of images to build a three-dimensional model of the subject; calculating one or more body measurements of the subject based on the three-dimensional model; and outputting the one or more body measurements.

The flat-panel imaging device may capture the plurality of images using millimeter-wave technology. In some embodiments, the flat-panel imaging device comprises a metamaterial, and an aperture of the flat-panel imaging device comprises a metamaterial aperture.

According to another aspect, detecting that a subject is in proximity to the flat-panel imaging device may include detecting motion of the subject via the flat-panel imaging device.

Capturing the plurality of images may include automatically capturing the plurality of images in real-time as the subject moves past the flat-panel imaging device. In addition, capturing may include one or more of: (i) simulating a radiation patterns of an aperture; (ii) simulating a propagation of radiation patterns over a scene; (iii) simulating a scattering of radiation from the scene; (iv) simulate backscattered radiation at the aperture; (v) simulating depth camera signals for region of interest detection; and (vi) performing image reconstruction from simulated measurements.

In one embodiment, processing the plurality of images to build a three-dimensional model of the subject includes stitching the plurality of images. The stitching process may include registering the plurality of images to align the images in a common coordinate system, calibrating the images to account for variations in the image formation process, and blending overlapping images.

According to yet another aspect, the plurality of images depict the subject in different states of deformation. Therefore, blending the plurality of images may include estimating a geometry and skeleton pose of the subject within each of the plurality of images. Estimating a geometry and skeleton pose of the subject within each of the plurality of images may include using a depth camera to constrain at least one region of interest within the plurality of images. In addition, stitching may include sampling each of the plurality of images at deformed vertex locations defined by the geometry and skeleton pose of the subject and mapping the sampled images to a standardized pose. Stitching may further include matching the estimated geometry and skeleton of the subject to a body type stored in a library of body types.

In some embodiments, outputting includes securely storing the one or more body measurements in a subject's electronic device, which may include one or more of a smart phone, tablet, laptop, personal computer, external storage device, and/or cloud storage.

Yet another aspect includes transmitting clothing data to the subject's electronic device. The clothing data may be used by the electronic device to simulate virtual clothing on a graphical representation of the subject based on the one or more body measurements. Subsequently, the one or more body measurements may be sent with user selections to a vendor system to facilitate a clothing purchase.

In certain embodiments, the stored body measurements may be transmitted from the subject's electronic device to a medical system to perform one or more of: a body mass index (BMI) calculation, prosthetic fitting, cast fitting, bandage fitting, and/or monitoring of at least one body dimension over time. In other embodiments, the stored body measurements may be transmitted from the subject's electronic device to a physical fitness application to monitor, for example, weight loss, fat loss, and/or muscle gain.

In another aspect, a system for acquiring body measurement information includes a real-time flat-panel millimeter-wave imaging device configured to detect a presence of a subject and, in response, automatically capture a plurality of millimeter-wave images of the subject. The system may also include a processor configured to process a plurality of millimeter-wave images to build a three-dimensional model of the subject, calculate one or more body measurements of the subject based on the three-dimensional model, and output the one or more body measurements.

In still another aspect, a non-transitory computer-readable medium includes program code that, when executed by a processor, cause the processor to perform a method comprising: detecting that a subject is in proximity to a flat-panel imaging device; capturing, via the flat-panel imaging device, a plurality of images; processing the plurality of images to build a three-dimensional model of the subject; calculating one or more body measurements of the subject based on the three-dimensional model; and outputting the one or more body measurements.

Other aspects of the present disclosure include all that is described and illustrated herein.

### BRIEF DESCRIPTION OF THE DRAWINGS

The accompanying Figures and Examples are provided by way of illustration and not by way of limitation. The foregoing aspects and other features of the disclosure are explained in the following description, taken in connection with the accompanying example figures relating to one or more embodiments, in which:

FIG. 1 is a schematic illustration of a flat-panel imaging device and a prototype system in accordance with an embodiment of the present disclosure;

FIG. 2 illustrates three-dimensional reconstructions of a mannequin target from actual measured data and simulated data in accordance with an embodiment of the present disclosure;

FIG. 3 is a flowchart of a method of acquiring body measurement information from a subject in accordance with an embodiment of the present disclosure;

FIG. 4 illustrates an unstitched and stitched images made from several images from different perspectives in accordance with an embodiment of the present disclosure;

FIG. 5 is a flow chart of a stitching process in accordance with an embodiment of the present disclosure;

FIG. 6 illustrates the geometry of an object that is specified and rigged with a skeleton in a default rest pose in accordance with an embodiment of the present disclosure;

FIG. 7 illustrates an experimentally measured skeleton in accordance with an embodiment of the present disclosure;

FIG. 8 illustrates a three-dimensional image captured using the flat-panel imaging device of FIG. 1 and stitched in accordance with an embodiment of the present disclosure;

FIG. 9A illustrates a library of body shapes parametrized by body measurements in accordance with an embodiment of the present disclosure;

FIG. 9B illustrates new bodies being synthesized from the library by specifying body measurements in accordance with an embodiment of the present disclosure; and

FIG. 10 is a schematic diagram of a system for acquiring body measurement information from a subject in accordance with an embodiment of the present disclosure.

### DETAILED DESCRIPTION

For the purposes of promoting an understanding of the principles of the present disclosure, reference will now be made to various embodiments and specific language will be used to describe the same. It will nevertheless be understood that no limitation of the scope of the disclosure is thereby intended, such alteration and further modifications of the disclosure as illustrated herein, being contemplated as would normally occur to one skilled in the art to which the disclosure relates.

Articles “a” and “an” are used herein to refer to one or to more than one (i.e. at least one) of the grammatical object of the article. By way of example, “an element” means at least one element and can include more than one element.

“About” is used to provide flexibility to a numerical range endpoint by providing that a given value may be “slightly above” or “slightly below” the endpoint without affecting the desired result.

The use herein of the terms “including,” “comprising,” or “having,” and variations thereof, is meant to encompass the elements listed thereafter and equivalents thereof as well as additional elements. As used herein, “and/or” refers to and encompasses any and all possible combinations of one or more of the associated listed items, as well as the lack of combinations where interpreted in the alternative (“or”).

As used herein, the transitional phrase “consisting essentially of” (and grammatical variants) is to be interpreted as encompassing the recited materials or steps “and those that do not materially affect the basic and novel characteristic(s)” of the claimed invention. Thus, the term “consisting essentially of” as used herein should not be interpreted as equivalent to “comprising.”

Moreover, the present disclosure also contemplates that in some embodiments, any feature or combination of features set forth herein can be excluded or omitted. To illustrate, if the specification states that a complex comprises components A, B and C, it is specifically intended that any of A, B or C, or a combination thereof, can be omitted and disclaimed singularly or in any combination.

Recitation of ranges of values herein are merely intended to serve as a shorthand method of referring individually to each separate value falling within the range, unless otherwise indicated herein, and each separate value is incorporated into the specification as if it were individually recited herein. For example, if a concentration range is stated as 1% to 50%, it is intended that values such as 2% to 40%, 10% to 30%, or 1% to 3%, etc., are expressly enumerated in this specification. These are only examples of what is specifically intended, and all possible combinations of numerical values between and including the lowest value and the highest value enumerated are to be considered to be expressly stated in this disclosure.

Unless otherwise defined, all technical terms used herein have the same meaning as commonly understood by one of ordinary skill in the art to which this disclosure belongs.

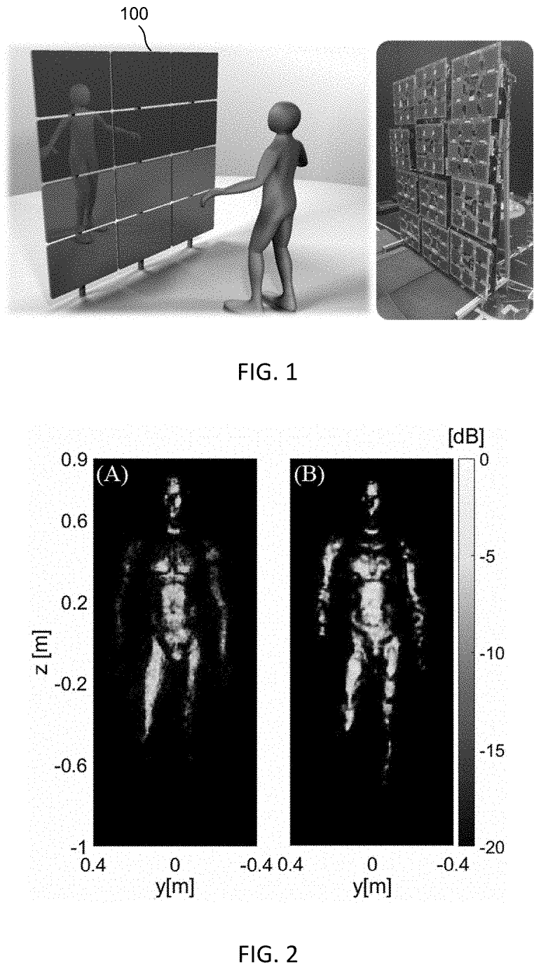

FIG. 1 depicts a flat-panel imaging device 100 according to one aspect of the present disclosure. The flat-panel imaging device 100 may operate, in some embodiments, in the millimeter-wave spectrum. However, a person of ordinary skill in the art will recognize that images may be acquired using shorter or longer wavelengths of electromagnetic radiation. Furthermore, while the flat-panel image device 100 may operate in real time to capture multiple images per second of a moving subject, non-real-time solutions may be used in some applications.

The left side of FIG. 1 is a schematic illustration of a subject standing in front of a conceptual flat-panel imaging device 100. The right side of FIG. 1 is a photograph of a prototype real-time flat-panel millimeter-wave imaging device used to acquire some of the images depicted herein (e.g., FIGS. 2, 4 and 8).

In some embodiments, the flat-panel imaging device 100 produces diffraction-limited (-7 mm at K-band) images of humans or other subjects at a 7 Hz shutter rate. For example, FIG. 2 illustrates three-dimensional reconstructions of a mannequin target from actual measured data (left) and simulated data (right).

Flat-panel imaging devices 100 have been described by, e.g., Gollub, J. et al. 2017 Scientific Reports, Vol. 7; Hunt, J. et al., 2013, Science, vol. 39, pg. 310-313; Yurduseven, O. et al., 2016, IEEE Microwave and Wireless Components Letters, vol. 26, pg. 367-369; Marks, D. et al., 2016, JOSA A, vol. 33, pg. 899-912), U.S. patent application Ser. No. 16/138,552, filed Sep. 21, 2018, for “Systems and Methods for Sensing a Lifeform Using Dynamic Metasurface Antennas,” with inventors Jonah Gollub, Kenneth Trofatter, Seyedmohammadreza Imani, and David Smith, and U.S. patent application Ser. No. 15/769,950, filed Nov. 14, 2016, for “Printed Cavities for Computational Microwave Imaging and Methods of Use,” with inventors Okan Yurduseven, Vinay Ramachandra, Gowda, Jonah Gollub, and David R. Smith, the disclosures of which are incorporated herein by reference in their entireties to the extent such subject matter is not inconsistent herewith.

In some embodiments, the flat-panel imaging device 100 comprises one or more metamaterials, which are artificial materials engineered to have one or more properties not found in naturally occurring materials. In particular, the metamaterials may be artificial composites that gain their electrical properties from their structures rather than inheriting them directly from the materials of which they are composed. As such, the aperture of the flat-panel imaging device 100 may comprise a metamaterial aperture.

As described more fully hereafter, the system further comprises a computer having at least a processor and memory, the computer being configured to run software that is able to perform one or more of the following functions: (i) simulate the radiation patterns of any type of aperture; (b) simulate the propagation of radiation patterns over the scene; (iii) simulate the scattering of radiation from a scene; (iv) simulate the backscattered radiation at the aperture; (v) simulate depth camera signals for region of interest detection; and (vi) perform image reconstruction from simulated measurements. Arbitrary scenes can be digitized or modeled, and qualitatively accurate images can be fully simulated. The software allows accurate and fast modeling to the point that reconstructions performed on synthetic data are nearly indistinguishable from physical scenes.

The system may further include an electronic device used by the subject, such as a personal computer, mobile phone, tablet, external storage device, cloud storage, and the like, where images obtained from the flat-panel imaging device 100 can be stored and accessed.

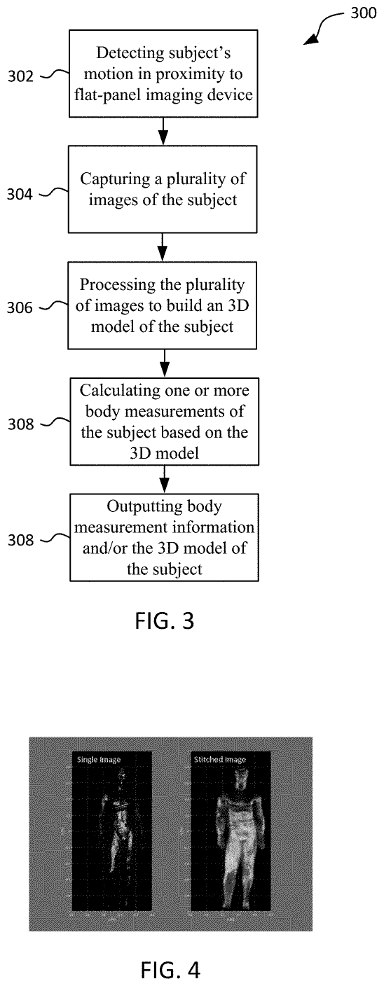

Referring to FIG. 3, another aspect of the present disclosure is a method 300 of acquiring body measurement information from a subject. The method 300 may comprise, consist of, or consist essentially of the steps: detecting 302 a subject's motion in proximity to a flat-panel imaging device 100, such as the rea-time millimeter-wave flat-panel imaging device described in connection with FIG. 1; capturing 304 a plurality of images of the subject; processing 306 the plurality of images to build a three-dimensional model of the subject's body; outputting 308 body measurement information and/or the 3D model of the subject.

Detecting 302 a subject's motion in proximity to the flat-panel imaging device 100 may be accomplished, for example, using one or more of the techniques described in U.S. patent application Ser. No. 16/138,552, filed Sep. 21, 2018, for “Systems and Methods for Sensing a Lifeform Using Dynamic Metasurface Antennas,” which is incorporated by reference herein.

In one embodiment, when the subject's motion is detected and/or in response to a user command, the flat-panel imaging device 100 may capture 304 a plurality of millimeter images. Millimeter images safely penetrate clothing while strongly reflecting from the skin.

The plurality of millimeter images are then “stitched” into a single full model of the subject in a standard pose, which can then be used to determine body measurements. The shutter rate of the flat-panel imaging device 100 may be fast enough (e.g., 7 Hz) to image people while walking, in contrast to conventional systems that require people to strike a pose while being scanned.

People deform as they move, which complicates machine learning approaches that conventionally expect people to be in a standardized pose. Additionally, mirror-like specular reflection is an issue for reflective objects that are smooth on the scale of millimeter waves. As the human body is smooth at these scales, specular reflection is often responsible for limiting scene coverage to specular highlights.

Commercial millimeter security systems mitigate this issue by requiring people to strike a standardized pose and then collecting measurements from many directions by mechanically scanning antennas in a nearly 360-degree fashion that maximizes coverage. Neither of these options are available for a stationary flat-panel imaging device 100 that images people in motion. If a walking person can be imaged in real-time, then the relative motion of the person and imager can be exploited to obtain a set of images with a diversity of perspectives and overlapping coverage of the scene. These images are then stitched together to produce a single three-dimensional model of the person.

FIG. 4 illustrates an unstitched image (left) and a stitched image (right) made from several images from different perspectives. As shown, the unstitched image suffers from specularity, which limits coverage. By contrast, stitching together several images from different perspectives (such as when the mannequin is moved or rotated) improves coverage.

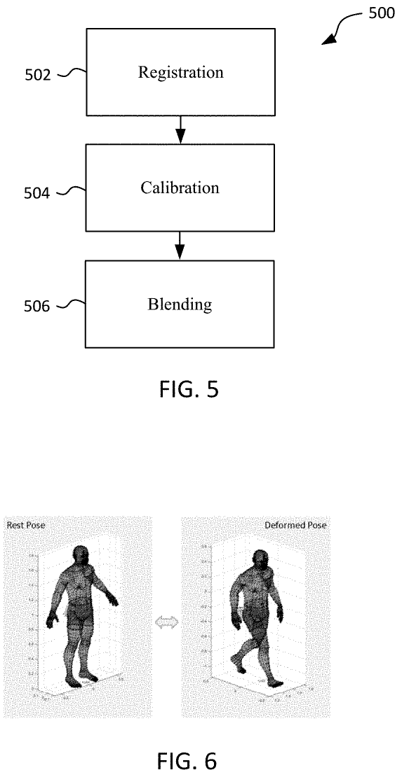

Referring to FIG. 5, the stitching process 500 is divided, in one embodiment, into three tasks: registration 502, to align images; calibration 504, to account for variations in the image formation process; and blending 506, to combine overlapping images.

Registration 502 is the process of transforming different sets of data into one coordinate system. Various registration methods are known, including intensity- and feature-based registration, transformational models, and the like. In intensity- and feature based registration, one of the images is referred to as the moving or source and the others are referred to as the target, fixed or sensed images. Image registration involves spatially transforming the source/moving image(s) to align with the target image. The reference frame in the target image is typically stationary, while the other datasets are transformed to match to the target.

Intensity-based methods compare intensity patterns in images via correlation metrics, while feature-based methods find correspondence between image features such as points, lines, and contours. Intensity-based methods register entire images or sub-images. If sub-images are registered, centers of corresponding sub images are treated as corresponding feature points.

By contrast, feature-based methods establish a correspondence between a number of especially distinct points in images. Knowing the correspondence between a number of points in images, a geometrical transformation is then determined to map the target image to the reference images, thereby establishing point-by-point correspondence between the reference and target images.

Image registration algorithms can also be classified according to the transformation models they use to relate the target image space to the reference image space. The first broad category of transformation models includes linear transformations, which include rotation, scaling, translation, and other affine transforms. Linear transformations are global in nature, thus, they cannot model local geometric differences between images.

The second category of transformations allow “elastic” or “nonrigid” transformations. These transformations are capable of locally warping the target image to align with the reference image. Nonrigid transformations include radial basis functions (thin-plate or surface splines, multiquadrics, and compactly-supported transformations), physical continuum models (viscous fluids), and large deformation models (diffeomorphisms).

Transformations are commonly described by a parametrization, where the model dictates the number of parameters. For instance, the translation of a full image can be described by a single parameter, a translation vector. These models are called parametric models. Non-parametric models on the other hand, do not follow any parameterization, allowing each image element to be displaced arbitrarily.

Known software systems for image registration include SimpleElastix®, an open source image registration program frequently used in medical image registration, which is available from Erasmus Medical Center, Biomedical Imaging Group Rotterdam, Rotterdam, the Netherlands, and Leiden University Medical Center, Division of Image Processing, Leiden, the Netherlands. Another image registration package is I2K ALIGN®, available from DualAlign LLC of Clifton Park, N.Y.

As noted above, calibration 504 accounts for variations in the image formation process, such as amplitude variation between consecutive image formations. Various image calibration tools are known in the art, including the Image Calibration and Analysis Toolbox, available via open source from the University of Exeter, Exeter, United Kingdom.

In one embodiment, the system makes use of an arbitrarily realistic skeleton deformation model. In computer graphics, complex object geometry can be modeled with multitudes of simple vertices, edges, faces. This geometry can be associated with the bones of a skeleton armature. Deformation is achieved by posing the skeleton and taking weighted averages of vertices with respect to different bones, as shown in FIG. 6. This effectively reduces the degrees of freedom needed to specify complicated geometric deformation, simplifying the description of the model. For example, the geometry of the subject in FIG. 6 is specified and rigged with a skeleton in a default rest pose. Posing the bones of the skeleton allows for realistic deformation of geometry.

In other embodiments, one or more depth cameras (as provided, for example, by the flat-panel imaging device 100) are used to constrain a region of interest in the images and can also be used to estimate the geometry and skeleton pose of a person in motion. Stitching is performed by sampling images at deformed vertex locations and mapping back to a standardized pose.

In one embodiment, a Kinect 2® system, available from Microsoft Corporation, and a 3D animation package, Blender, available via open source from the Blender Foundation of Amsterdam, Netherlands, may be used in the process of blending 506.

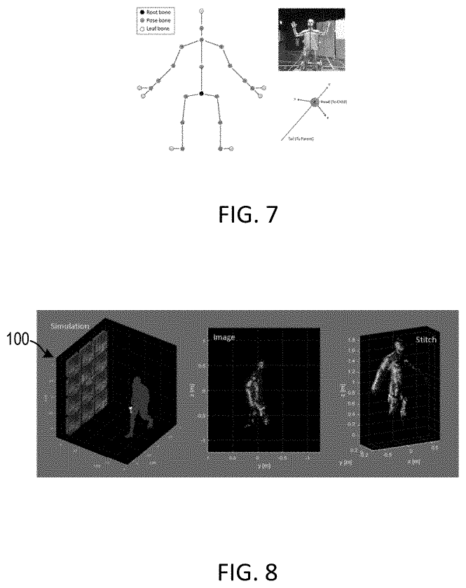

For example, as shown in FIG. 7, a Kinect skeleton model consists of 25 bones. Each bone has a local coordinate system that is posed with respect to its parent bone. An experimentally measured skeleton (right) is depicted as being overlaid upon the image of a subject. The goal is to estimate the geometry of the person and to accurately estimate the deformation skeleton of the subject.

FIG. 8 illustrates a three-dimensional image captured using a flat-panel imaging device 100 and stitched according to the above-described techniques. A reconstructed/stitched image is shown on the right.

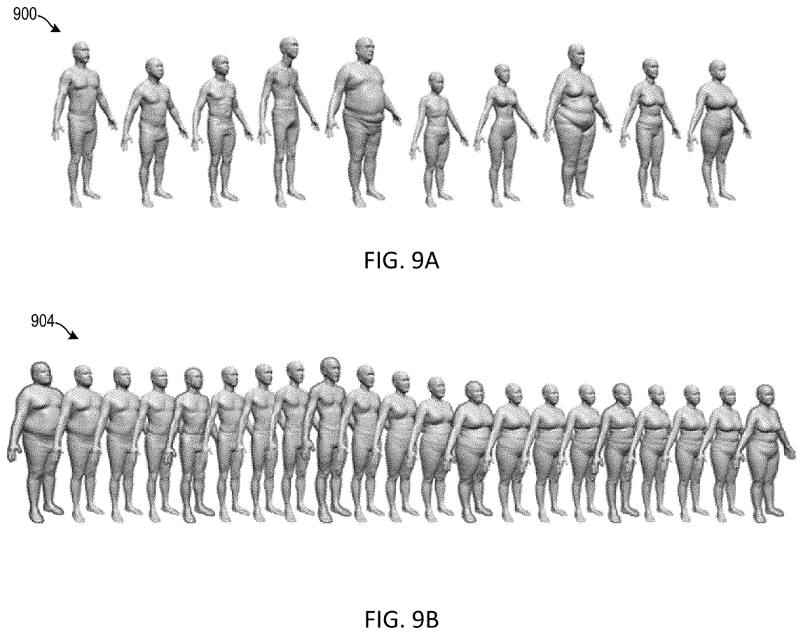

In one embodiment, the skeleton pose and its geometry are appropriately matched to the body type of the subject being imaged using sensor fusion. In one embodiment, this is achieved with a library 902 of body shapes parametrized by body measurements, as shown in FIG. 9A. Such libraries 902 of human targets are available for purchase, for example, from the Civilian American and European Surface Anthropometry Resource Project (CAESAR). The CAESAR project collected thousands of range scans of volunteers aged 18-65 in the United States and Europe. The raw range data for each individual consists of four simultaneous scans from a Cyberware® whole body scanner. These data were combined into surface reconstructions using mesh stitching software. Each reconstructed mesh may contain 250,000-350,000 triangles, with per-vertex color information.

In one embodiment, initial guesses of a person's geometry and pose are achieved by using depth camera(s) to estimate some body measurements and generating a geometric body model, boot-strapping the stitching process. After several millimeter wave images are taken, a stitched millimeter wave image can be generated and analyzed to refine estimates on body parameters and pose. The refined estimates can update the geometric model iteratively until convergence. The mapping between body measurements and geometry can be learned the library 902. New bodies 904 can be synthesized from the library 902 by specifying body measurements, as shown in FIG. 9B. Realistic clothes can be added and animated for simulating more realistic depth camera signals.

Once a three-dimensional representation of the subject is generated in a common coordinate space, the distance, d, between points (x₁, y₁, z₁) and (x₂, y₂, z₂) may be calculated according to the equation:

d=(x₂−x₁)²+(y₂−y₁)²+(z₂−z₁)²)^{1/2} (1)

Standard measurements (bust/chest, waist, hip, inseam, etc.) may be derived from key points identified in the library 902 and/or determined from geometrical features of the three-dimensional representation of the subject.

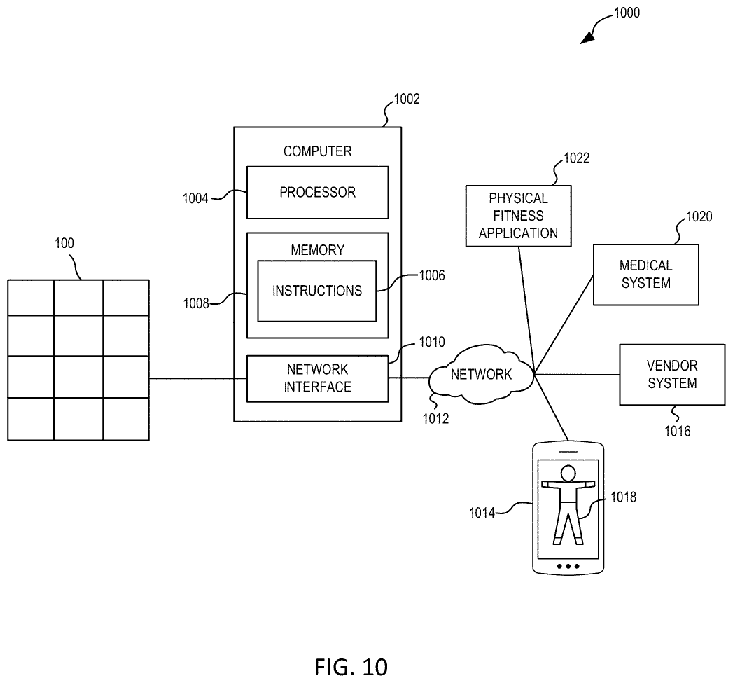

FIG. 10 is a schematic diagram of a system 1000 for acquiring body measurement information from a subject. As noted earlier, the system 1000 may include a flat-panel imaging device 100, such as the real-time millimeter-wave flat-panel imaging device described in reference to FIG. 1. Millimeter-wave images generated by the flat-panel imaging device 100 may be received by a computer 1002. The computer may include a processor 1004, which may be embodied, without limitation, as a microprocessor, application-specific integrated circuit (ASIC), digital signal processor (DSP), field-programmable gate array (FPGA) or the like. In some embodiments, the processor 1004 may execute instructions 1006 stored in a memory 1008 to perform aspects of the methods described herein. The memory 1008 may be embodied, without limitation, as any suitable combination of random access memory (RAM), read only memory (ROM), electrically erasable read only memory (EEPROM), magnetic and/or optical storage, cloud storage, or the like.

The computer 1002 may further include a wired and/or wireless network interface 1010 for connecting the computer 1002 to a network 1012, such as a local area network (LAN) or a wide area network (WAN), such as the Internet. The same or a different network interface 1010 may be used to receive image data from the flat-panel imaging device 100. The network interface 1010 may implement any suitable wired or wireless networking protocols, including, without limitation, Ethernet, 802.11x, HTTP, FTP, TCP/IP, and the like.

As described in connection with FIG. 3, the system 1000 may detect a subject's motion in proximity to the flat-panel imaging device 100, capture a plurality of millimeter images; process the plurality of images to build a 3D model of the subject; and output body measurement information and/or the 3D model of the subject.

The computer 1002 may send the body measurement information via the network 1012 to an electronic device 1014 of the subject, such as a smart phone (depicted), tablet, laptop, personal computer, external storage device, and/or cloud storage. For privacy, the body measurement information may be securely stored in the subject's electronic device 1014 without retaining copies thereof in the computer 1002 and/or flat-panel imaging device 100.

In one embodiment, a vendor system 1016 (which may be implemented as a computer server, cloud application, or the like) may send clothing information, including, without limitation, clothing types, images, 3D models, measurements, prices, etc., to the subject's electronic device 1014. Using the body measurement information and clothing information, the subject's electronic device 1014 may generate a graphical representation 1018 (simulation or virtual rendering) of the subject wearing one or more items of clothing. Software systems for rendering three-dimensional models on a computing device 1014 are known in the art, including Unity Real-Time Development Platform, available from Unity Technologies of San Francisco, CA, Blender, available from Blender Foundation of Amsterdam, Netherlands, and Maya, available from Autodesk Corporation of San Rafael, Calif. In some configurations, the graphical representation 1018 may be presented solely on the subject's electronic device 1014 to alleviate privacy concerns. In other embodiments, the graphical representation 1018 may be displayed in a store, kiosk, semitransparent mirror, or the like (not shown).

If desired, the subject may place an order with the vendor system 1016, which may include transmitting at least a portion of the body measurement information and one or more clothing selections, quantities, etc., to the vendor system 1016.

The present disclosure is not limited to consumer apparel shopping. In one embodiment, at least a portion of the body measurement information may be transmitted to a medical system 1020 (which may be implemented as a computer server, cloud application, or the like), where the information may be used in BMI calculations, prosthetic/bandage/cast fitting, monitoring body dimension(s) over time (e.g., weight loss) or other instances where body dimensions are needed.

In other embodiments, the body measurement information may be sent to a physical fitness application 1022, which may be hosted on the subject's electronic device 1014 and/or a remote server or cloud application accessible by the network 1012 (as illustrated). The body measurement information may be used by the physical fitness application 1022 to, e.g., monitor body dimensions over time, including, without limitation, weight loss, muscle gain, and the like.

The systems and methods described herein can be implemented in hardware, software, firmware, or combinations of hardware, software and/or firmware. In some examples, systems described in this specification may be implemented using a non-transitory computer readable medium storing computer executable instructions that when executed by one or more processors of a computer cause the computer to perform operations. Computer readable media suitable for implementing the control systems described in this specification include non-transitory computer-readable media, such as disk memory devices, chip memory devices, programmable logic devices, random access memory (RAM), read only memory (ROM), optical read/write memory, cache memory, magnetic read/write memory, flash memory, and application-specific integrated circuits. In addition, a computer readable medium that implements a control system described in this specification may be located on a single device or computing platform or may be distributed across multiple devices or computing platforms.

One skilled in the art will readily appreciate that the present disclosure is well adapted to carry out the objects and obtain the ends and advantages mentioned, as well as those inherent therein. The present disclosure described herein are presently representative of preferred embodiments, are exemplary, and are not intended as limitations on the scope of the present disclosure. Changes therein and other uses will occur to those skilled in the art which are encompassed within the spirit of the present disclosure as defined by the scope of the claims.

No admission is made that any reference, including any non-patent or patent document cited in this specification, constitutes prior art. In particular, it will be understood that, unless otherwise stated, reference to any document herein does not constitute an admission that any of these documents forms part of the common general knowledge in the art in the United States or in any other country. Any discussion of the references states what their authors assert, and the applicant reserves the right to challenge the accuracy and pertinence of any of the documents cited herein. All references cited herein are fully incorporated by reference, unless explicitly indicated otherwise. The present disclosure shall control in the event there are any disparities between any definitions and/or description found in the cited references.

What is claimed is:

1. A method comprising:
detecting that a subject is in proximity to a flat-panel imaging device;
capturing, via the flat-panel imaging device, a plurality of images;
processing the plurality of images to build a three-dimensional model of the subject;
calculating one or more body measurements of the subject based on the three-dimensional model; and
outputting the one or more body measurements.

2. The method of claim 1, wherein the flat-panel imaging device captures the plurality of images using millimeter waves.

3. The method of claim 1, wherein detecting that the subject is in proximity to the flat-panel imaging device comprises detecting motion of the subject via the flat-panel imaging device.

4. The method of claim 1, wherein capturing the plurality of images comprises automatically capturing the plurality of images in real-time as the subject moves past the flat-panel imaging device.

5. The method of claim 1, wherein the flat-panel imaging device comprises a metamaterial.

6. The method of claim 5, wherein the flat-panel imaging device comprises an aperture, and wherein the aperture comprises a metamaterial aperture.

7. The method of claim 5, wherein capturing comprises at least one of:
(i) simulating a radiation patterns of an aperture; (ii) simulating a propagation of radiation patterns over a scene; (iii) simulating a scattering of radiation from the scene; (iv) simulate backscattered radiation at the aperture; (v) simulating depth camera signals for region of interest detection; and (vi) performing image reconstruction from simulated measurements.

8. The method of claim 1, wherein processing the plurality of images to build a three-dimensional model of the subject comprises stitching the plurality of images.

9. The method of claim 8, wherein stitching the plurality of images comprises:
registering the plurality of images to align the images in a common coordinate system.

10. The method of claim 9, wherein at least a subset of the registered plurality of images overlap, and wherein stitching the plurality of images comprises:
blending the plurality of images by combining the at least a subset of the overlapping registered plurality of images.

11. The method of claim 10, wherein the plurality of images comprise images of the subject in different states of deformation, and wherein blending the plurality of images comprises:
estimating a geometry and skeleton pose of the subject within each of the plurality of images.

12. The method of claim 10, wherein estimating a geometry and skeleton pose of the subject within each of the plurality of images comprises:
using a depth camera to constrain at least one region of interest within the plurality of images.

13. The method of claim 11, wherein stitching comprises:
sampling each of the plurality of images at deformed vertex locations defined by the geometry and skeleton pose of the subject; and
mapping the sampled images to a standardized pose.

14. The method of claim 11, wherein stitching further comprises matching the geometry and skeleton pose of the subject to a body type stored in a library of body types.

15. The method of claim 1, wherein outputting comprises:
securely storing the one or more body measurements in a subject's electronic device.

16. The method of claim 15, wherein the subject's electronic device comprises at least one of a smart phone, a tablet, a laptop, and a personal computer.

17. The method of claim 15, further comprising:
transmitting clothing data to the subject's electronic device, wherein the clothing data is configured to cause the subject's electronic device to simulate clothing on a graphical representation of the subject based on the stored one or more body measurements.

18. The method of claim 15, further comprising:
transmitting the stored one or more body measurements to a vendor system to facilitate a clothing purchase.

19. The method of claim 15, further comprising:
transmitting the stored one or more body measurements from the subject's electronic device to a medical system to perform one or more of:
a body mass index (BMI) calculation,
a prosthetic fitting,
a cast fitting,
a bandage fitting, and
monitoring at least one body dimension over time.

20. The method of claim 15, further comprising:
transmitting the stored one or more body measurements from the subject's electronic device to a physical fitness application to monitor weight loss, fat loss, and/or muscle gain.

21. A system comprising:
a real-time flat-panel millimeter-wave imaging device configured to detect a presence of a subject and, in response to the presence of the subject being detected, automatically capture a plurality of millimeter-wave images of the subject; and
a processor configured to process the plurality of millimeter-wave images to build a three-dimensional model of the subject, calculate one or more body measurements of the subject based on the three-dimensional model, and output the one or more body measurements.

22. The system of claim 21, wherein the flat-panel imaging device comprises a metamaterial, and wherein an aperture of the flat-panel imaging device comprises a metamaterial aperture.

23. A non-transitory computer-readable medium comprising program code that, when executed by a processor, cause the processor to perform a method comprising:
detecting that a subject is in proximity to a flat-panel imaging device;
capturing, via the flat-panel imaging device, a plurality of images;
processing the plurality of images to build a three-dimensional model of the subject;
calculating one or more body measurements of the subject based on the three-dimensional model; and
outputting the one or more body measurements.
